(19) United States
(12) Patent Application Publication
(10) Pub. No.: US 2009/0029067 A1
(43) Pub. Date: Jan. 29, 2009

(54) METHOD FOR PRODUCING AMORPHOUS CARBON COATINGS ON EXTERNAL SURFACES USING DIAMONDOID PRECURSORS

(76) Inventors: Steven F. Sciamanna, Orinda, CA (US); Andrew W. Tudhope, Danville, CA (US); Robert M. Carlson, Petaluma, CA (US); William J. Boardman, Danville, CA (US); Thomas B. Casserly, San Ramon, CA (US); Pankaj Jyoti Hazarika, San Leandro, CA (US); Deepak Upadhyaya, Fremont, CA (US)

Correspondence Address: MARK J. ROSEN P.C., 418 BARCLAY ROAD, BRYN MAWR, PA, 19010, US

(21) Appl. No.: 12/113,254

(22) Filed: May 1, 2008

Related U.S. Application Data
(60) Provisional application No. 60/946,914, filed on Jun. 28, 2007.

(51) Int. Cl. C23C 16/513

(52) U.S. Cl. 427/577

(57) ABSTRACT

The invention relates to a method for forming high sp³ content amorphous carbon coatings deposited by plasma enhanced chemical vapor deposition on external surfaces. This method allows adjustment of tribological properties, such as hardness, Young's modulus, wear resistance and coefficient of friction as well as optical properties, such as refractive index. In addition the resulting coatings are uniform and have high corrosion resistance. By controlling pressure, type of diamondoid precursor and bias voltage, the new method prevents the diamondoid precursor from fully breaking upon impact with the substrate. The diamondoid retains sp³ bonds which yields a high sp³ content film at higher pressure. This enables a faster deposition rate than would be possible without the use of a diamondoid precursor.

The present invention relates to the deposition of carbon based coatings onto the surfaces of articles and relates particularly, but not exclusively, to the deposition of such coatings onto metallic surfaces such as, for example an external surface.

The present invention relates particularly but not exclusively to high sp³ content amorphous carbon coatings on surfaces of articles, particularly but not exclusively, external surfaces produced by plasma enhanced chemical vapor deposition (PECVD) using a high concentration of diamondoid precursors. A method of controlling ion bombardment energy to deposit coatings with properties ranging from diamond-like carbon (DLC) to high sp³ content hydrocarbon polymeric is also disclosed.

### BACKGROUND OF THE INVENTION

Prior art coating methods for formation of diamond-like carbon include chemical vapor deposition (CVD), physical vapor deposition (PVD), and plasma enhanced chemical vapor deposition (PECVD) methods. Many of the desirable properties of DLC are determined by the amount of carbon that undergoes sp³ bonding (diamond) compared to the amount of carbon that undergoes sp² bonding (graphite). By increasing the sp³/sp² ratio it is possible to achieve many of the excellent tribological properties of diamond, such as high hardness and high Young's modulus, low wear and low friction, as well as corrosion resistance and uniform film properties.

Composite coatings based on DLC have also been shown to have desirable properties. For example, layered films using a material of low modulus followed by a material of high hardness (e.g., tungsten carbide/carbon) have been shown to have increased wear resistance. Similarly, a “nano-composite” can be used. A nano-composite is formed by mixing the materials instead of layering, so that the nano-sized crystals of a very hard material (e.g., TiN) are embedded in the amorphous DLC matrix. A nano-composite can also involve two or more different amorphous matrices, such as a C—H matrix and separate metal-metal matrix as described in U.S. Pat. No. 7,786,068 to Dorfman et al. In the prior art, high quality films were not produced solely by PECVD techniques, but rather by PVD techniques or a hybrid PVD/PECVD method.

The formation of prior art DLC films is fully described in “Diamond-Like amorphous carbon,” J. Robertson, Materials Science and Engineering R 37 (2002) pages 129-281; incorporated herein by reference. The commonly accepted model of DLC formation is commonly referred to as the subplantation model.

Prior art PECVD of DLC based coatings relies on ion bombardment energy to form sp³ bonds. Without this, graphite will form instead of diamond. It has been found that approximately 100 eV of energy on the C+ ion is needed to maximize the sp³ content. At very high ion energy, films with high sp² content are formed. At very low ion energy, the result from prior art techniques is high hydrogen content polymers. Carbon ion energy is a function of bias voltage, pressure, precursor gas and plasma density. High plasma density, low pressure (<1e⁻³ Torr) PECVD techniques such as electron cyclotron resonance have generated the highest sp³ content PECVD films, with reports of up to 70% sp³ content. However these processes are limited to low pressure so the deposition rate is very slow (˜1 μm/hr).

The deposition of DLC coatings is well described in Massler (U.S. Pat. No. 6,740,393), this coating description includes an adhesion layer, gradient layer and DLC top coating. One of the advantages taught by Massler is a high deposition rate process preferably in the range from 1-4 microns/hour at a pressure from 10⁻³ to 10⁻² mbar (0.75-7.5 m Torr), the maximum hardness given in the examples taught by Massler is 2,500 HK. In comparison the present invention achieves a much higher deposition rate with high hardness and a higher operational pressure. A comparison of prior art (Massler) and the present invention process parameters are shown below:

| | Massler | Invention |
|---|---|---|
| Process Parameters | (Example 2) | (Example A) |
| Pressure (mtorr) | 0.75-7.5 | 200 |
| Argon flow (sccm) | 50 | 200 |
| Acetylene flow (sccm) | 350 | 0 |
| Adamantane flow (liquid ccm) | 0 | 0.05 (6 sccm gas) |
| Voltage (V) | 700 | 1000 |
| RF Power (watts) | | 10 |
| Magnets | Yes | No |
| Deposition rate (um/hr) | 1.5 | 7.05 |
| Hardness (GPa) | 25 | 23.6 |

The above is an example of the process and does not limit the range of the invention, for example the process can be optimized to provide a higher hardness than the above at a somewhat lower deposition rate or it can be optimized to provide a high deposition rate with a lower hardness.

Higher pressure (>10 m Torr) PECVD techniques have the advantage of higher deposition rates, however with prior art techniques it is not possible to make high sp³ content films due to the lack of a collision-less plasma sheath. This means that the mean free path of the ion is less than that of the plasma sheath width, resulting in low ion energy. Additionally, the ratio of (free) radicals to ions is higher at high pressure which results in sp² rich films. A high level of radicals vs. ions is detrimental to DLC properties, as radicals are highly reactive but lack the energy of ions. To form high quality DLC it is important to have a large portion of film deposition due to ion flux vs. non-ionized (or radical) flux, due to the importance of ion bombardment energy. Since the ion/radical ratio decreases with increasing pressure, prior art processes for sp³ formation were limited to low pressure, and the resulting low deposition rates that go along with low pressure.

There is a trend in increasing hardness with increasing saturation, or sp³ bonding, of the precursor molecule. This is because molecules such as acetylene with two pi bonds are more likely to form reactive radicals than a molecule such as methane with sp³ bonding or no pi bonds. Thus a higher hardness film is produced by methane then acetylene, conversely due to the higher radical reactivity the acetylene based coating will have a higher deposition rate than the methane based coating.

Most prior art precursors are hydrocarbons such as methane, acetylene and benzene. The precursor used to form the film will change the carbon energy due to the breakup of the molecule on impact with the surface. Thus a carbon atom produced from acetylene (C₂H₂) will have approximately one-half the energy of a carbon atom from methane (CH₄). Therefore a high bias voltage is normally required to produce high sp³ content films when larger precursor molecules are used. The use of a large hydrocarbon precursor can also have negative effects, such as a large thermal spike.

Prior art PECVD techniques contained substantial amounts of hydrogen due to the hydrogen contained in the hydrocarbon precursor which is incorporated into the DLC. This hydrogen has detrimental effects such as lowering the hardness and temperature stability of the coating.

Compared to CVD techniques, PECVD allows coating at lower temperature because the energy is supplied by the plasma rather than heat. This is important in the instance where the substrate is temperature-sensitive.

Plasma immersion ion implantation and deposition (PIID) techniques have been shown to be useful for coating the external surfaces of complex shapes. PIID is performed by applying a negative bias to a workpiece, and this bias will pull positive ions toward the workpiece if the plasma sheath is conformal. There are also improvements that can be made to film properties such as adhesion and film density via ion bombardment of the workpiece.

Use has been made of high sp³ seed material in prior art PECVD formation of carbon-coated O₂ barrier films on plastic materials. For example, EP 0763 144 B1 uses a diamondoid precursor at very low concentration (<10%) compared to the concentration of a standard hydrocarbon precursor such as acetylene. In the prior art, however, the ability to control film properties is limited by both the low concentration of diamondoid and the inability to control ion bombardment energy.

Diamondoids of the adamantane series are hydrocarbons composed of fused cyclohexane rings that form interlocking cage structures that are very stable. The lower diamondoids have chemical formulas of C₄ₙ₊₆H₄ₙ₊₁₂ where n is equal to the number of cage structures. A complete description of these materials can be found in “Isolation and Structure of Higher Diamondoids, Nanometer-Sized Diamond Molecules” (Dahl, Liu & Carlson, Science, January 2003, Vol. 299); incorporated herein by reference. The first three unsubstituted diamondoids are adamantane, diamantane and triamantane.

The term “diamondoids” refers to substituted and unsubstituted caged compounds of the adamantane series including adamantane, diamantane, triamantane, tetramantane, pentamantane, hexamantane, heptamantane, octamantane, nonamantane, decamantane, undecamantane, and the like, including all isomers and stereoisomers thereof. The compounds have a “diamondoid” topology, which means their carbon atom arrangement is superimposable on a fragment of an FCC diamond lattice. Substituted diamondoids comprise from 1 to 10 and preferably 1 to 4 independently-selected alkyl substituents. Diamondoids include “lower diamondoids” and “higher diamondoids,” as these terms are defined herein, as well as mixtures of any combination of lower and higher diamondoids.

The term “lower diamondoids” refers to adamantane, diamantane and triamantane and any and/or all unsubstituted and substituted derivatives of adamantane, diamantane and triamantane. These unsubstituted lower diamondoid components show no isomers or chirality and are readily synthesized, distinguishing them from “higher diamondoids.”

The term “higher diamondoids” refers to any and/or all substituted and unsubstituted tetramantane components; to any and/or all substituted and unsubstituted pentamantane components; to any and/or all substituted and unsubstituted hexamantane components; to any and/or all substituted and unsubstituted heptamantane components; to any and/or all substituted and unsubstituted octamantane components; to any and/or all substituted and unsubstituted nonamantane components; to any and/or all substituted and unsubstituted decamantane components; to any and/or all substituted and unsubstituted undecamantane components; as well as mixtures of the above and isomers and stereoisomers of tetramantane, pentamantane, hexamantane, heptamantane, octamantane, nonamantane, decamantane, and undecamantane.

Adamantane chemistry has been reviewed by Fort et al. in “Adamantane: Consequences of the Diamondoid Structure,” Chem. Rev. vol. 64, pp. 277-300 (1964). Adamantane is the smallest member of the diamondoid series and may be thought of as a single cage crystalline subunit. Diamantane contains two subunits, triamantane three, tetramantane four, and so on. While there is only one isomeric form of adamantane, diamantane, and triamantane, there are four different isomers of tetramantane (two of which represent an enantiomeric pair), i.e., four different possible ways of arranging the four adamantane subunits. The number of possible isomers increases non-linearly with each higher member of the diamondoid series, pentamantane, hexamantane, heptamantane, octamantane, nonamantane, decamantane, etc.

Adamantane, which is commercially available, has been studied extensively. The studies have been directed toward a number of areas, such as thermodynamic stability, functionalization, and the properties of adamantane-containing materials. For instance, the following patents discuss materials comprising adamantane subunits: U.S. Pat. No. 3,457,318 teaches the preparation of polymers from alkenyl adamantanes; U.S. Pat. No. 3,832,332 teaches a polyamide polymer forms from alkyladamantane diamine; U.S. Pat. No. 5,017,734 discusses the formation of thermally stable resins from adamantane derivatives; and U.S. Pat. No. 6,235,851 reports the synthesis and polymerization of a variety of adamantane derivatives. The use of lower diamondoid moieties in conventional polymers is known to impart superior thermal stability and mechanical properties.

### SUMMARY OF THE INVENTION

The invention described herein relates to the PECVD technique, although it is also applicable to the PVD process.

A method, in accordance with some embodiments of the present invention, allows production of high sp³ content amorphous carbon coatings deposited by PECVD techniques on external surfaces. The coatings have desirable mechanical and tribological properties as well as chemical and corrosion inertness. By controlling pressure, type of diamondoid precursor and bias voltage, the new method provides surface precursors that retain sp³ bonds in a tight carbon cluster which yields a high sp³ content film at higher pressure. This enables a faster deposition rate than would be possible without the use of a diamondoid precursor.

According to one aspect of the present invention there is provided a method of forming a diamond-like carbon coating by plasma enhanced chemical vapor deposition comprises the steps: creating a reduced atmospheric pressure adjacent a surface to be treated; introducing a diamondoid precursor gas to said surface; establishing a bias voltage between a first and a second electrode; and establishing a plasma region adjacent said surface; wherein, said diamondoid precursor gas contains diamondoids of the adamantine series and said pressure and bias voltage are above 20 m Torr and 600 V such as to cause the deposition of diamond-like coarbon on said surface whilst retaining a high deposition rate of greater than 4 μm/hr.

According to another aspect of the present invention there is provided a method of forming a diamond-like carbon coating by plasma enhanced chemical vapor deposition comprising the steps: creating a reduced atmospheric pressure adjacent a surface to be treated; introducing a diamondoid precursor gas to said surface; establishing a bias voltage between an anode and a cathode with a first power source; and establishing a plasma region adjacent said surface with a second power source; wherein, said diamondoid precursor gas contains diamondoids of the adamantane series and said pressure and bias voltage are selected such as to cause the deposition of diamond-like carbon on said surface. This approach may also employ the pressures and bias voltages mentioned above.

Each of the above may adopt one or more of the following steps or materials. For example, the precursor may be selected from the group consisting of: adamantane, diamantane, triamantane and 1,3 dimethyl-adamantane, and combinations thereof in which the 1,3 dimethyl-adamantane may be alkylated. The adamantane may be present as a percentage of between 10% and 100% in another reactive gas and the operating pressure may be selected to be between 20 m Torr and 200 m Torr and the bias voltage between 600V and 3000V. In some arrangements it may be desirable to including the step of introducing a hydrocarbon with the diamondoid precursor such as C₂H₂ or C₄H₈. Additionally, the method may include the step of adding a metal to the precursor, which may be tetrakisdimethylamino-titanium (TDMAT). The method may also include the step of layering diamondoid without any other reactive gas and other reactive gases with or without diaomondoid to form composite coatings and may include a step of adding a dopant to said diamondoid precursor which may be selected from the group consisting of: N₂, silicon, germanium or a metal containing MOCVD precursor which may comprise TDMAT, and combinations thereof. In a preferred arrangement both said first and second supplies are in electrical contact with said first electrode which is in electrical contact with said surface, and said first and second supplies have separate return electrodes Additionally, said first power supply is a preferably a DC pulse supply and said second power supply is an RF supply.

It is contemplated that composites formed by the process described herein are novel. It is further contemplated that films and/or coatings defined by the process are also novel.

### BRIEF DESCRIPTION OF THE DRAWINGS

FIG. 1 depicts a PECVD system for depositing DLC films, in accordance with some embodiments of the present invention;

FIG. 2 depicts a detailed view of a DLI system for use in accordance with some embodiments of the present invention;

FIG. 3 is a graphical representation of the controllable parameters during an optimized operating cycle;

FIG. 4 is a chart of test data illustrating the improvement in ductility and hardness for various process parameters and diamondoid concentrations in the processing gas mixture, as used on an external coating process;

FIG. 5 is a graph of hardness as a function of DMA concentration in C₂H₂ obtained from tests carried out on an internal coating process;

FIG. 6 is a chart of test data illustrating the improvement in coating properties for various process parameters and DMA concentrations in the processing gas mixture, as used on an internal coating process;

FIG. 7 is a chart of test data illustrating the coating properties created using DMD;

FIG. 8 is a chart of test data for various test conditions in which the percentage diamondoid was varied;

FIG. 9 is a graph of deposition rate associated with the data of FIG. 8; and

FIG. 10 and FIG. 11 illustrate the wear characteristics of coatings produced in accordance with the present invention as a comparison with prior art processes.

### DETAILED DESCRIPTION

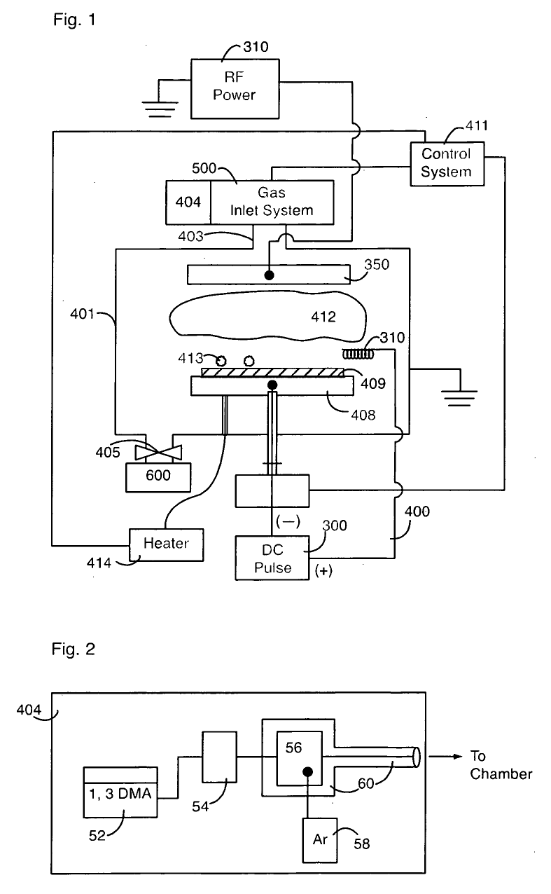

With reference to FIG. 1, a workpiece 409 is placed inside a vacuum chamber 401 and is connected to a biasing system 300, gas inlet system 500 and pumping system 600. The biasing system consists of a power supply that applies negative bias to the workpiece. The negative bias is used to (a) increase plasma intensity close to the workpiece, (b) draw an ionized reactive gas to the surface to be coated, (c) allow ion bombardment of the film to improve film properties such as density and stress levels. In a preferred embodiment, a DC pulse power supply 300 provides the negative bias. This allows control over the film uniformity since the duty cycle can be adjusted to control heating. It also permits replenishment of the source gas and allows discharge of positive surface charge buildup, both of which can occur during the “off” portion of the cycle and which can result in arcing on an insulating film such as DLC. To further improve charge dissipation, an asymmetric bipolar pulse can be used with a very small short positive pulse applied to attract electrons and dissipate the positive charge. A second power supply, in this case an RF power source 310, is used to generate the plasma in the chamber and to increase the plasma density in the chamber. This important feature allows independent control of the workpiece bias voltage without significantly affecting the plasma in the chamber. In a further embodiment of the invention the second power source could be an ion gun or induction coils. Here, the workpiece 409 functions as a cathode, or is connected to the cathode, while the chamber wall or separate electrodes function as the anodes 310 and are connected to the positive side of the pulsed DC supply. An electrode 350 above the workpiece is coupled to the RF supply with the return being the chamber walls. In a preferred arrangement both said first and second supplies are in electrical contact with said first electrode which is in electrical contact with said surface, and said first and second supplies have separate return electrodes Additionally, said first power supply is a preferably a DC pulse supply and said second power supply is an RF supply. Such an arrangement allows the application of the RF voltage on top of a DC pulse which may be used to advantage.

In a desirable optional step the workpiece is sputter-cleaned and an adhesion-promoting layer is deposited as follows: The chamber is coupled to a vacuum source and to a source of gas. The interior of the chamber is pumped to low base pressure to remove volatile organics. Argon is introduced into the chamber and the pressure is raised to a few m Torr using the throttle valve 405. An argon plasma is generated in the chamber when a negative voltage bias is applied between the anode and cathode. The negative bias causes ion bombardment and sputter cleaning of the workpiece. After the argon cleaning, a silicon containing adhesion layer is deposited, such that a strong silicide bond is formed to the workpiece, in this case a steel substrate, and so that a SiC bond is formed to the amorphous carbon coating when deposited. In the case where the metal substrate does not form a strong bond with silicon, it may be desirable to use a precursor other than silicon for the adhesion layer. The strength of the bond that is formed is indicated by a negative heat of formation of the compound; the larger the negative number the more readily the chemical bond will form thermodynamically.

Following the deposition of the adhesion layer, the diamondoid based amorphous carbon film is formed. This is done by injecting the diamondoid precursor vapor into the chamber. Preferred diamondoid precursors are liquid at standard conditions with sufficient vapor pressure to be delivered to a vacuum chamber. This includes purified alkylated diamondoids or mixtures of alkylated diamondoids, including alkylated adamantane, alkylated diamantane, alkylated triamantane, and the rest of the adamantane series. Preferred diamondoid precursors also include liquid mixtures of isomers of diamantane containing one or more alkyl groups.

Adamantane's ionization potential (IP) is reported as 9.25 eV in the NIST data base (National Institute of Standards, NIST Chemistry webbook, http://webbook.nist.gov/chemistry/). Other diamondoids have been calculated by Lu, et al. to show similar IP, ranging between 7 and 9 eV for diamondoids containing from 2 to 10 cages in “Electronic and Vibrational Properties of Diamond-like Hydrocarbons” Physical Review B 72, 035447 (2005). Unsubstituted diamondoids are readily ionized to both cations and radical cations in the plasma deposition chamber of this invention. Diamondoid cations are unusually stable and can remain intact during their acceleration to the negatively biased work piece surface. Diamondoid cation stability is demonstrated by unusually intense, positively charged molecular ions observed during mass spectral measurements as shown by Waltman and Ling in “Mass Spectrometry of Diamantane and Some Adamantane Derivatives” Canadian Journal of Chemistry, Volume 58, pages 2189 to 2195 (1980). Polfer, Sartakov and Oomens showed that diamondoid cations and diamondoid radical cations can survive for many hundreds of milliseconds in vacuum in “The Infrared Spectrum of the Adamantyl Cation” in Chemical Physics Letters, Volume 400, pages 201 to 205 (2004). It has been found from mass spectral analysis that cations formed from alkylated diamondoids are predominately radical cations. The radical diamondoid cations are formed through the loss of the alkyl group as a neutral species, and the intact diamondoid cage structure retains the charge. A radical diamondoid cation has one hydrogen atom less than a diamondoid cation, which results in a coating with less hydrogen content. In addition, the radical diamondoid cations can cross link with each other at the surface more readily than diamondoid cations can cross link.

If diamondoid cations or radical diamondoid cations are accelerated to the workpiece with too great a velocity, destruction of their cage structure is possible. However, this invention makes it possible to adjust cation energies using a range of bias voltages and pressures to minimize (or maximize) such destruction.

A preferred diamondoid precursor is 1,3 dimethyl adamantane. Though purified adamantane is a solid, this substituted form of adamantane is a liquid at room temperature conditions. 1,3 dimethyl adamantane has been found to give high sp³ content, uniform film properties, low hydrogen content and fast deposition rate in the range of process pressures 10 m Torr to 1 Torr. The liquid can be delivered to the workpiece by either of the known techniques of bubbling or direct liquid injection (DLI). A preferred method shown in FIG. 2 is the DLI system (and is a detailed schematic of 404). A small measured amount of liquid (e.g. 0.5 cm³/min) from the pressurized canister (52) is injected from the liquid flow controller (52) into an evaporation chamber 56. Heating coils 60 heat the solution to a temperature exceeding the boiling point of the 1,3 dimethyl adamantane solution at 100 mTorr (e.g., 100° C.). A carrier gas such as N₂ or Argon 58 is also introduced. Any diamondoid precursor delivery line or other component between the evaporator and the pipe must also be heated to prevent condensation.

Many of the diamondoid forms exist as solids at standard conditions; these can be delivered by heating the solid so that sufficient vapor is generated by sublimation. In this situation, a carrier gas can be used to increase the delivery pressure and all downstream delivery lines should be heated.

This novel improvement method includes using a combination of pressure, size of diamondoid precursor and bias voltage to moderate ion bombardment energy such that the diamondoid precursor does not fully break up on impact with the substrate but remains with partially intact sp³ bonds. For the bonds to remain partially intact the ion energy per carbon atom must be controlled to a low value (<400 eV at 100 mTorr). In the present invention, plasma or ion generation and workpiece bias are each controlled by a separate power supply; however, induced self-generated bias by RF capacitive coupling to the workpiece is contemplated. In a preferred embodiment of the invention, the system is operated at fairly low pressure (˜150 m Torr) such that few or no ion collisions occur across the plasma sheath and the substrate bias can then be directly used to set ion bombardment energy. If the bias is set low (<400 eV) then the diamondoid precursor does not breakup fully on impact with the surface, but bonds together to form a high sp³ content film. Using this technique to maintain low ion energy, an optically clear, high refractive index, sp³ bonded polymer with low hydrogen content was obtained. Using this technique to maintain moderate ion energy, a hard DLC film with low hydrogen content and high sp³ content was obtained. It is important to note that the ion density within the chamber can be kept high using the second non-biasing power supply (via RF plasma, ion gun or induction coil). This has several advantageous effects: a thin plasma sheath is maintained so that ion collisions are reduced and ion energy is controlled; a high deposition rate is maintained; and conformal coatings can be obtained over complex geometries due to the thin sheath.

Additionally, ion energy per carbon atom can be reduced by increasing the system pressure (which causes ion collisions across the plasma sheath) or by increasing the size (more specifically the molecular weight) of the precursor molecule. For example, if 1,3 dimethyl adamantane is used as the precursor and the process pressure is set high enough (>100 mTorr) such that the result is collisions across the plasma sheath, then the ion energy upon impact will be greatly reduced compared to the applied bias voltage. This technique can also be used to control ion energy and vary the sp³ content and properties of the film. The use of high pressure has the additional advantage of increased deposition rate. The molecular weight of the diamondoid can also be used to lower the energy per carbon atom. For example, diamantane (C₁₄H₂₀) can be substituted for adamantane (C₁₀H₁₆). These ion energy control techniques enable the formation of a higher sp³ content film than would be available without the use of diamondoid precursor. It also enables a much higher deposition rate than smaller hydrocarbons such as acetylene due to the presence of many more carbon atoms per molecule, while still producing a high sp³ content film.

The advantages of using larger diamandoid molecules such as dimethyl-diamantine (which is the next largest diamondoid following dimethyl-adamantane) and dimethyl-triamantane (larger still following dimethyl-diamantine) include the following: 1) A continuing increase in deposition rate based on a larger number of carbon molecules per ion, or for each Amp of current delivered to the workpiece a larger number of sp³ carbon atoms is delivered, 2) a higher ratio of carbon/hydrogen is obtained, 3) carbon energy per ion is controlled based on precursor molecule size, such that coating properties can be controlled, including forming high sp³ clear polymer coatings requiring low bias. This is due to the fact that as the diamondoid molecule becomes larger, the energy per carbon atom decreases for a constant bias voltage and 4) A larger ratio of sp³ bonded carbon content within the coating should be obtained based on the high number of sp³ carbon atoms delivered by the precursor compared to sp² bonding that may occur when joining precursor molecules together during film formation.

The duty cycle is used to control heating of the workpiece. The duty cycle is also used with the small, short-duration positive bias to allow dissipation of positive charge from the workpiece.

A further advantage of this method is that novel layered composite materials can be formed by varying the bias voltage, pressure or diamondoid precursor as previously described. Materials with layers of softer, tougher sp³ polymer and layers of hard DLC are contemplated, thus forming a composite with a combination of the desirable properties of the combined layers.

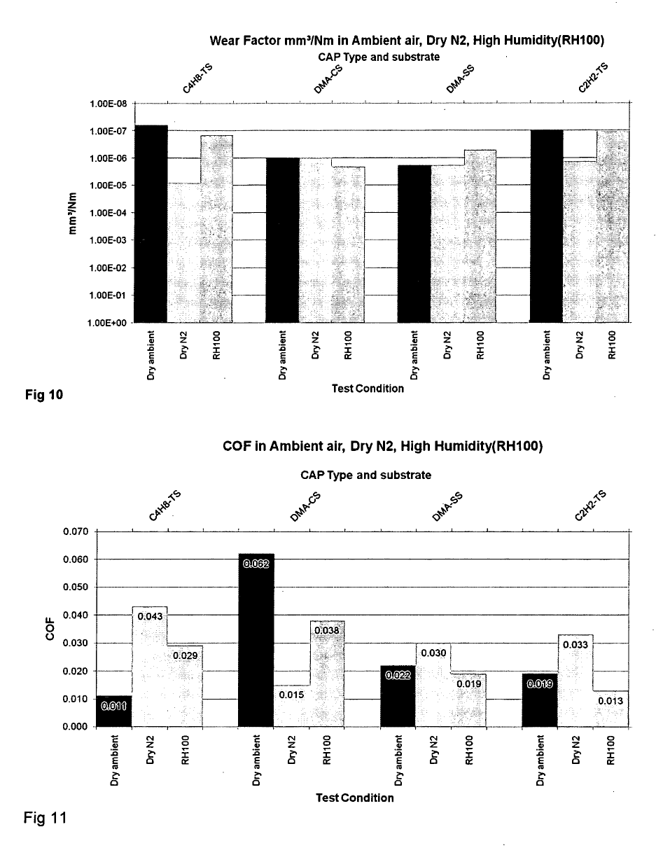

A further advantage of the method is that prior art DLC's are known to have increased COF and wear rate in low humidity environments. The use of diamondoid based DLC provides a consistently low COF and wear rate at all levels of humidity including low humidity (see FIGS. 10 and 11)

In another embodiment of the invention, a hydrocarbon is added to the diamondoid precursor to promote bonding between the diamondoid fragments in the coating. A hydrocarbon with a low hydrogen content that is easily fragmented, such as acetylene, should be used. The concentration of hydrocarbon added to the diamondoid precursor will generally not exceed 75 mol % of the total reactive gas. The addition of this type of hydrocarbon will produce a film with improved mechanical and tribological properties and allow the deposition of a thicker film.

In another embodiment of the invention, molecular precursors containing elements other than hydrogen and carbon are added to the diamondoid to enhance mechanical and tribological properties. In addition to forming films with improved properties, these materials can be used to lower the electrical resistance of the film and thus produce a thicker film. For example, a metal-containing precursor such as tetrakis-(dimethylamino) titanium (TDMAT) can be added to enhance electrical conductivity and to produce a thicker film when DC pulse bias is used.

Additionally, metal layers may be added by sputtering or evaporation. Other materials that can be used with a diamondoid precursor include nitrogen, silicon or metal organic chemical vapor deposition (MOCVD) precursors such as TDMAT. PVD sources can be added to the process to sputter or evaporate metal in the presence of the diamondoid precursor (or in alternating layers of metal and DLC) to improve properties such as the increased adhesion of a metal adhesion layer or improved ductility and toughness. In addition to forming various composite films with improved tribological or corrosion resistant properties, these dopants can be used to lower the electrical resistance of the film and thus produce a thicker film.

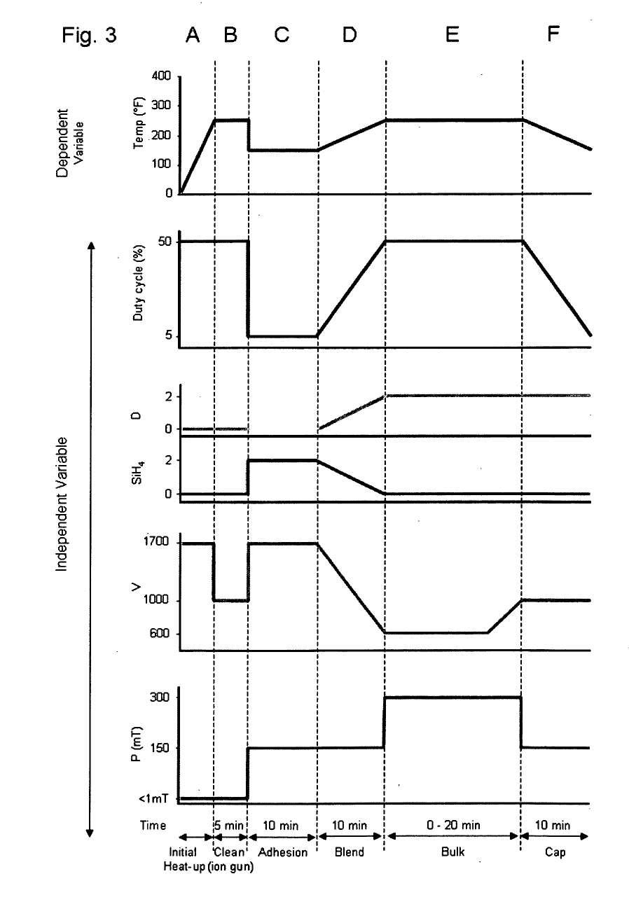

FIG. 3 illustrates graphically the control and variation of the controllable parameters during an optimised treatment cycle. Other variations form this arrangement may be contemplated, particularly if it is desired to optimize for another parameter. From FIG. 3 it will be appreciated that an initial heat up step A may be achieved by using a voltage of about 1700 V and a Duty Cycle of about 50% and a low pressure of about 1 mTorr for an appropriate period of time depending on the component such as to raise the temperature to about 300° C.

The optional cleaning step B may be achieved at a reduced voltage setting of 1000 V for about 5 minutes in Argon with a flow rate of about 500 sccm and an RF power of about 10 W without altering any other controllable parameters.

The next step (step C) comprises the application of an adhesion layer which requires the raising of the voltage V to, for example, 1700 V, the raising of the pressure to, for example, 150 m Torr and the introduction of Silane (SᵢH₄) at about 250 sccm or other such suitable gas, into the feed stream whilst dropping the duty cycle to, for example, 5%. This will deposit a generally well bonded but soft layer onto which subsequent layers may be more easily bonded.

Step D introduces a blend layer in which the properties of the coating vary from high adhesion to high hardness and may be achieved by, for example, ramping the voltage from 1700 V to 600 V whilst raising the duty cycle to 40% whilst also ramping increasing the diamondoid concentration to 0.050 sccm in an Argon atmosphere at about 20 sccm and ramping reducing the Silane (SᵢH₄) concentration.

Bulk deposition takes place in step E which is maintained as long as is desired in order to deposit a desired thickness of sp³ rich coating. The pressure, power and bias voltage may be altered or controlled as necessary so as to produce a coating with desired properties, as will be discussed immediately below. Towards the end of the bulk deposition step E it may be desirable to increase the bias voltage V in preparation of the final layer. The silane may be turned off in this step to form pure DLC.

A final cap layer may be applied in step F and the duty cycle returned to 5%, the combination of which will reduce the temperature and also blend out the final layer. The silane may be turned off in this step.

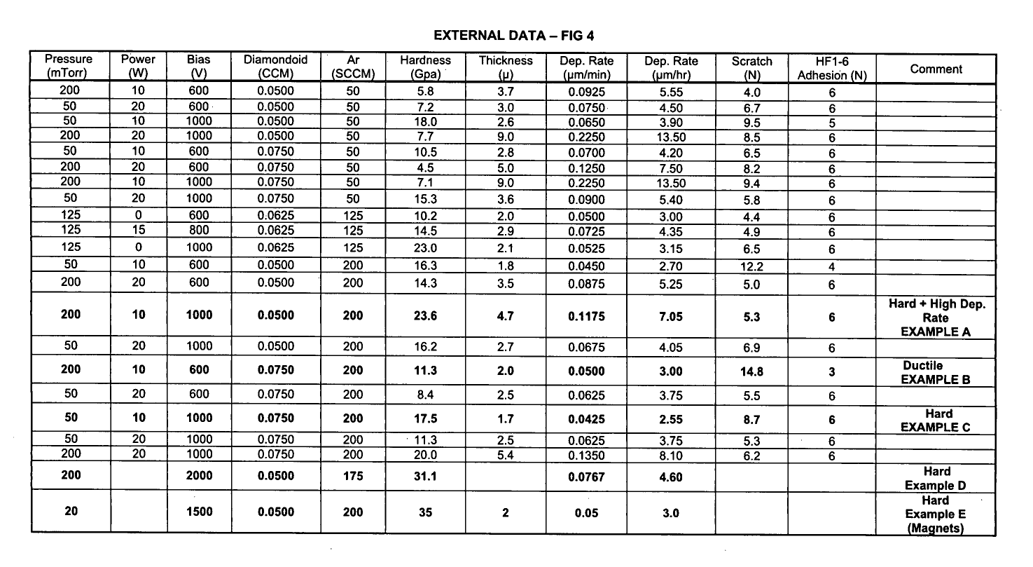

It will be appreciated that the ratio of controllable parameters such as pressure, Power, % diamondoid, and argon flow may be altered or varied during the bulk deposition step E such as to modify the final properties as desired. FIG. 4 provides details of how the hardness, thickness, deposition rate, scratch resistance and adhesion properties vary as these controllable parameters are varied and from which it will be appreciated that the samples marked A, B, C and D make for good comparison. Example A provides a surface with a high hardness at 23.6 Gpa and a high deposition rate at 7.05 μm/hr. To achieve this, the Pressure was 200 m Torr, the Power was set at 10 W, the bias voltage at 1000 V and a diamondoid flow of 0.05 ccm in an Argon flow of 200 sccm was employed. Example A has superior properties to the Massler sample discussed above. Example B provides a surface with good ductility and lower but acceptable hardness at 11.3 Gpa but a lower deposition rate of 3 μm/hr. The scratch resistance is, however, particularly good at 14.8 N. and the bias voltage need only be 600 V. Example C provides a surface with good hardness at 17.5 Gpa and an acceptable deposition rate at 2.55 μm/hr but manages to achieve this at a low pressure of just 50 m Torr. Example D very high dep rate of 13.5 um/hr with 7.7 GPa hardness. FIG. 4 also provides as example D the performance data for an example at 200 mTorr and a bias voltage of 2000V (10% DC). The DMA was 0.05 ccm and argon was at 175 based on an adhesion layer of silane in Argon at 1700V and 100 mTorr for 10 mins with no blend layer. A final tested hardness of 31.1 Gpa and a dep rate of 4.6 μm/hr was achieved. These are by far the best results and illustrate the advantage of greater bias voltages, particularly for external processes. FIG. 4 also provides in example E the performance for a 20 m Torr process, with a bias voltage of 1000V, DMA flow of 0.05 ccm and argon flow of 175 sccm, using magnets to increase plasma ionization, this produces the hardest coating at 35 GPa with a somewhat reduced deposition rate of 3 μm/min. FIG. 4 also provides in example E the performance for a 20 m Torr process, with a bias voltage of 1500 V, DMA flow of 0.05 ccm and argon flow of 200 sccm, using magnets to increase plasma ionization, this produces the hardest coating at 35 GPa with a somewhat reduced deposition rate of 3 microns/min so confirms the advantage of using magnets in such processes.

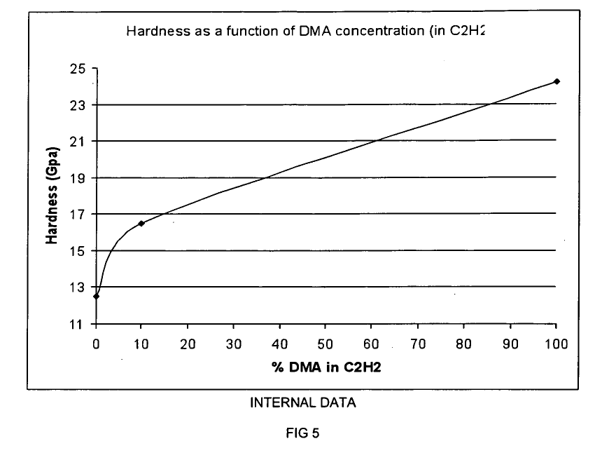

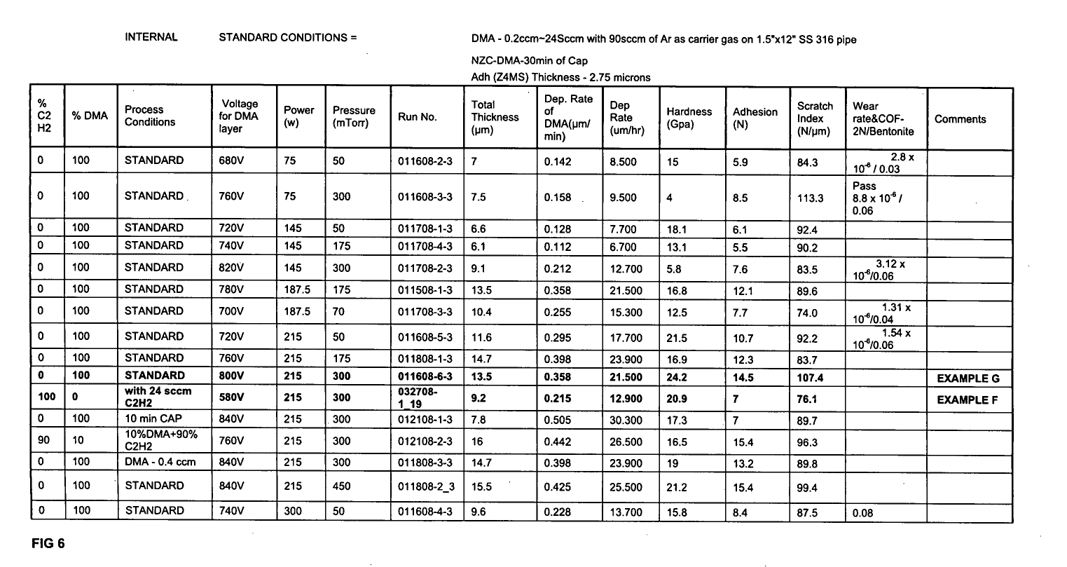

FIG. 5 illustrates the established relationship between hardness as a function of DMA concentration in C₂H₂ and from which it will be appreciated that the hardness increases rapidly between 0 and 11% DMA but also continues to increase strongly between 11% DMA and 100% DMA. It is this property that is exploited in the present invention. FIG. 6 provides the data from which the graph of FIG. 5 has been drawn.

The reader's attention is now drawn to FIG. 6 which illustrates the coating properties obtained using DMA with Argon as a carrier gas on an internal process employing the hollow cathode effect. Example F which was run with 100% C₂H₂/total reactive gas, with a flow rate of 24 sccm C₂H₂ and gave a hardness of 20.9 Gpa and a 12.9 μm/hr deposition rate. This can be compared with Example G which employed 100% DMA and produced a hardness of 24.2 Gpa at a much higher dep rate of 21.5 μm/hr. It will, therefore, be appreciated that the addition of the adamantane gives a 20% harder film with a much higher deposition rate (67% higher).

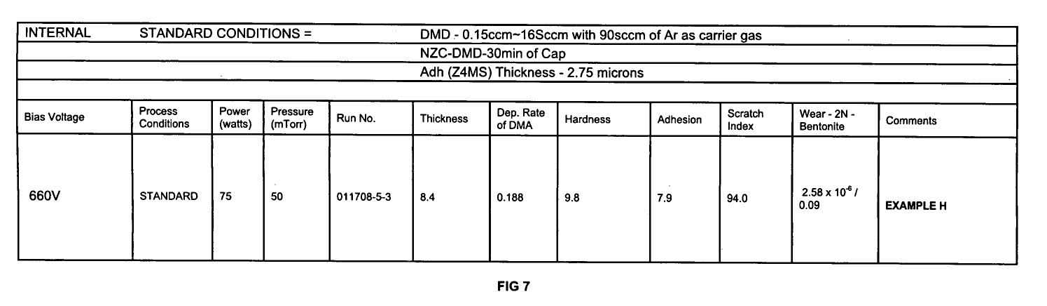

FIG. 7 provides data on a DMD coating process and from which it will be appreciated that the DMD process gives an increases deposition process compared to the adamantane process with the same conditions shown in row 1 of FIG. 6 (˜32% higher) with a reduced hardness. The reduction in hardness is due to the reduction in ion energy per carbon atom due to the larger molecule size, if the bias voltage was increased for the DMD comparable hardness to the DMA precursor could be obtained.

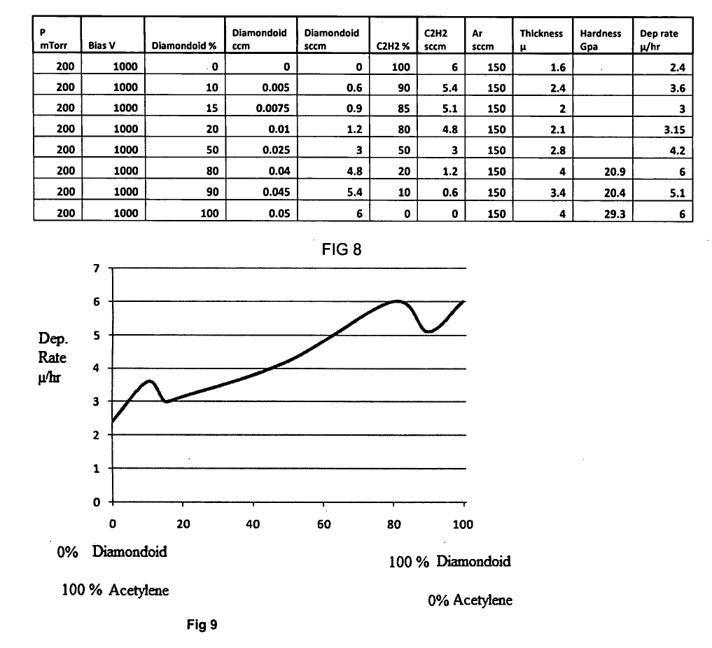

FIG. 8 provides data from a test conducted to establish the advantages associated with an increase in the percentage diamondoid in the carrier graph for constant pressure and bias voltage conditions. The data of FIG. 8 is represented graphically in FIG. 9 and from which it will be appreciated that there is a significant increase in the deposition rate as the percentage diamondoid is increased. It is also observed that the initial rise and then fall of deposition rate between zero and 15 percent diamondoid is arrested above 20% and a maximum is achieved at approximately 80% before a noticeable fall and then final rises to 6 p/hr. There may be some advantage to simply selecting 80% rather than 100% diamondoid.

FIG. 10 and FIG. 11 illustrate the wear characteristics of coatings produced with prior art precursors and those of the present invention and from which it will be appreciated that Diamondoid coatings give consistent wear and low COF in dry nitrogen or low humidity environments compared to other DLC's

Those skilled in the art will appreciate that the above process may be employed with other pre-cursor materials having high diamondoid structure such as, for example, dimethyl-diamantane and under such circumstances it would be appropriate to employ a higher bias voltage in the region of 1000- to 3000 V. It is also known in the art to add a metal to the precursor to add ductility and toughness, and increased electrical conductivity allowing thicker films and such a step may also be employed to advantage in the present invention. The metal may be, for example, tetrakisdimethylamino-titanium (TDMAT). Additionally, introducing the hydrocarbon in the form of C₂H₂ or C₄H₈ is known and may be employed in the present invention. The process of the present invention may also include the step of layering diamondoid without any other reactive gas and other reactive gases with or without diaomondoid to form composite coatings which is known in the art to provide improved ductility, hardness, toughness by layering hard, soft materials many times with superior properties than each material alone. Additionally, adding a dopant to said diamondoid precursor is also desirable and suitable examples include N₂, H₂, Sᵢ, metals, germanium or a metal containing MOCVD precursor such as TDMAT. In some instances the precursor may be alkylated. Composite coatings based on DLC have also been shown to have desirable properties. For example layered films using a material of low modulus followed by a material of high hardness such as WC/C has been shown to increase wear resistance. Similarly, a so called “nano-composite” can be used. A nano-composite is formed by mixing the materials instead of layering, so that nano-sized crystals of a very hard material (e.g. TiN) are embedded in the amorphous DLC matrix. A nano-composite can also involve two or more different amorphous matrixes, such as a C—H matrix and separate metal-metal matrix as described in U.S. Pat. No. 5,786,068 to Dorfman et al. In the prior art, these types of films have not been produced with good results with purely PECVD techniques, but only by PVD or hybrid PVD/PECVD methods. It will also be appreciated that higher bias voltages have been shown to provide further improvements in the coating quality and it will be appreciated that bias voltages of up to 3000 V may be employed.

What is claimed is:

1. A method of forming a diamond-like carbon coating by plasma enhanced chemical vapor deposition comprising the steps of:
(a) creating a reduced atmospheric pressure adjacent a surface to be treated;
(b) introducing a diamondoid precursor gas to said surface;
(c) establishing a bias voltage between a first electrode and a second electrode with a power source; and
(d) establishing a plasma region adjacent said surface;
wherein said diamondoid precursor gas contains diamondoids of the adamantane series and said pressure and bias voltage are selected such as to cause the deposition of diamond-like carbon on said surface.

2. The method of claim 1 wherein said pressure and bias voltage are above 20 m Torr and 600V respectively.

3. The method of claim 1 wherein the pressure is between 20 m Torr and 200 m Torr and the bias voltage is between 600V and 3000V.

4. The method of claim 1 wherein said precursor is selected from the group consisting of adamantane, diamantane, triamantane and combinations thereof.

5. The method of claim 1 wherein said precursor is alkylated.

6. The method of claim 1 wherein said diamondoid precursor is 1,3 dimethyl-adamantane.

7. The method of claim 1 wherein said adamantane is present as a percentage of between 10% and 100% in another reactive gas.

8. The method of claim 1 wherein magnets are used to increase ionization and allow low pressure operation of between 20 m Torr and 50 m Torr, with high deposition rate

9. The method of claim 1 further comprising the step of introducing a hydrocarbon with the diamondoid precursor.

10. The method of claim 9 wherein the hydrocarbon is in the form of C₂H₂ or C₄H₈.

11. The method of claim 1 further comprising the step of adding a metal to the precursor.

12. The method of claim 11 wherein the metal is tetrakisdimethylamino-titanium (TDMAT).

13. The method of claim 1 further comprising the step of layering diamondoid without any other reactive gas, and other reactive gases with or without diaomondoid, to form composite coatings.

14. The method of claim 1 further comprising the step of adding a dopant to said diamondoid precursor.

15. The method of claim 1 wherein the dopant is selected from the group consisting of: N₂, silicon, germanium, TDMAT, other metals containing MOCVD precursor, and combinations thereof.

16. The method of claim 1 wherein a second power source establishes a plasma adjacent to said surface.

17. The method of claim 16 wherein said pressure and bias voltage are above 20 m Torr and 50 V respectively and a deposition rate is greater than 4 μm/hr.

18. The method of claim 16 wherein the pressure is between 10 m Torr and 200 m Torr and the bias voltage is between 50 V and 500 V to produce a subset of said DLC coating including high sp³ content polymers.

19. The method of claim 16 wherein both said power source and second power source are in electrical contact with said first electrode, said first electrode is in electrical contact with said surface, and wherein said power source and second power source have separate return electrodes.

20. The method of claim 16 wherein said power source is a DC pulse supply and said second power source is an RF supply.

21. A product coated by the method of claim 1
